(19) United States
(12) Patent Application Publication
(10) Pub. No.: US 2010/0126561 A1
(43) Pub. Date: May 27, 2010

(54) SOLAR MODULE FOR PITCHED ROOF

(75) Inventor: Michael Reich, Nettetal (DE)

Correspondence Address: DARBY & DARBY P.C., P.O. BOX 770, Church Street Station, New York, NY, 10008-0770, US

(73) Assignee: c.m.s. GmbH, Nettetal (DE)

(21) Appl. No.: 12/597,266

(22) PCT Filed: Apr. 10, 2008
(86) PCT No.: PCT/EP2008/054330

§ 371 Date: Oct. 23, 2009

(30) Foreign Application Priority Data
Apr. 26, 2007 (DE) 10 2007 020 151.8

(51) Int. Cl. H01L 31/048; E04D 13/18

(52) U.S. Cl. 136/251; 52/173.3; 52/741.1

(57) ABSTRACT

The invention provides a device for attaching solar modules that enables an agreeable integration into a roof and which is easy to install. A frame is provided which consists of two lateral frame members, an upper and a lower frame member. Each of the four frame members comprises an area having a rectangular cross section with two long and two narrow sides. The four frame members are interconnected such that the long sides are disposed perpendicular to the main surface of the solar module or the solar cell. It is thereby achieved that the frame is torsion-resistant. Therefore, the solar module can be transported and mounted with comparatively few problems. Such a solar module is attached to a batten of a pitched roof with a projecting portion, in particular by bolting.

### CROSS-REFERENCE TO RELATED APPLICATIONS

This is the U.S. national phase application under 35 U.S.C. §371 of International Patent Application No. PCT/EP2008/054330 filed Apr. 10, 2008 and claims the benefit of German Application No. 10 2007 020 151.8, filed on Apr. 26, 2007. The International Application was published in the German language on Jun. 11, 2008 as International Publication No. WO 2008/132031 under PCT Article 21(2).

### FIELD OF INVENTION

The invention relates to a solar module for installation into a pitched roof, a pitched roof comprising solar modules and a method for mounting the solar modules.

### BACKGROUND OF THE INVENTION

The light of the sun is converted into useful energy, in particular into electrical energy, with a solar module within the meaning of the present invention. Other solar modules use the light of the sun for heating water.

A solar module for generating electrical current comprises a transparent, radiation and heat resistant cover, electrical terminals protected from corrosion, a protection of the brittle solar cell against mechanical impacts, handling and attaching means. Sufficient cooling is also to be ensured.

Solar modules are mounted, among other things, on roofs. Assemblies for mounting solar modules ensure that the aforementioned requirements are met, particularly where the generation of electrical power is concerned.

An assembly for mounting solar modules on roofs is also known from DE 202006018568 U1, in which a clamping device, with which a solar module is detachably attached to a roof, is attached to a base. DE 202006015917 U1 teaches the attachment of a solar plant on a house roof by means of supports.

Such solar modules that are to be attached on top of the tiles of a roof have a number of drawbacks. Firstly, their appearance is less than pleasing because they change the character of a roof. Secondly it is necessary to attach another covering in the form of the modules in addition to the tiles or another roof covering, which is not economically feasible.

Attaching solar modules on a special base and connecting the bases by means of tongue-and-groove connections is known from US RE38,988 E. The solar module and the bases are supposed to be applied to roofs of buildings. The base is not capable of protecting the solar modules, nor can it replace a leak-tight roof.

Thus, assemblies have been developed with which solar modules are integrated into a pitched roof. They are can replace a roof covering, that is, roofing tiles, for example.

DE 102004015305 A1 discloses a solar cell unit with a modular frame surrounding a solar module. The modular frame comprises a draining channel disposed along an edge of the modular frame. The draining channel prevents rain water from not reaching the area of a roof. The reliable attachment of the solar modules on a roof is problematic in this prior art. Because for reasons of costs, a solar module has to be attached to a roof much more securely as compared with roofing tiles. Disadvantageously, wind is easily able to act on the lower edges of the solar modules known from DE 102004015305 A1, thus lifting and prying them off.

Providing a roofing title with a recess into which a solar cell can be inserted in order to exploit solar energy is known from DE 19823356 A1. Cooling the cell already poses a problem. According to DE 19823356 A1, it is imperative that a heat exchanger be inserted for this purpose between the roofing tile and the solar cell, which, however, cannot be realized in practice in an economically viable manner for reasons of space. Moreover, there is a double covering, namely on the one hand the roofing tiles, and on the other hand the actual solar cell.

From JP 2002088993 A it is known to partially exchange roofing tiles for solar modules in a pitched roof.

The company Ubbink Econenergy Solar GmbH, Cologne, which can be visited on the internet at www.ubbinksolara.de, offers an attaching system for solar modules under the name InterSole which is attached underneath the roofing tiles. A plastic tray extending below the tiles is attached on the battens. This plastic tray is necessary in order to achieve leak-tightness. Aluminum rails are mounted on the plastic tray. The aluminum rails serve for accommodating the framed photovoltaic modules, i.e. the solar cells.

The modules abut edge to edge. Consequently, there remains a gap between the individual modules. Water may enter here. Thus, a plastic tray is required underneath the modules in order to ensure that the roof is water-proof. Similar to the modules set on the roof, this system is equipped with a system for making the roof leak-tight and with another system for generating energy. This makes things relatively expensive.

In order to arrive at an improved system, the company Conergy AG, Hamburg, which can be found at www.conergy.de, offers a system for mounting solar modules on a roof similar to roofing tiles. This means that the solar modules overlap in a manner similar to roofing tiles. For this purpose, rails are mounted on the battens perpendicular relative thereto. The rails serve for attaching the solar modules. The rails serve for accommodating frameless modules and must therefore be aligned in a very exact manner. Otherwise, the modules are exposed to lateral pressure which may cause the modules to crack. In order to achieve an overlap, the rail system has lips that provide for the appropriate distance in the overlapping area. This system has proven susceptible to failure since bending the lips in the wrong way causes the system to be leaky. Thus, mounting this known system requires a corresponding amount of work.

The rails enable the water to run off vertically between two modules. However, areas which extend through the roof will always remain in the transition area, particularly in the corner area. Thus, this system is not suited for roofs with a pitch of less than 30 degrees, because leak-tightness is not ensured in that case. Wind can press moisture, this is, rain and snow, through the leaky area into the interior of the roof.

From US 2004/0011354 A1, solar modules are known which comprise a frame which is of comparable thickness as the actual solar cell, i.e. the unit generating useful energy.

As is known in the case of roofing tiles, the frames, with an upper frame member, are hooked into a horizontal batten. The lower frame member rests on an adjacent upper frame member of a solar module adjacent thereunder. The frame member known from US 2004/0011354 A1 is very thin, insubstantially thicker than the actual solar cell. A thin frame offers correspondingly little protection against distortion which may cause the solar cell to break. Moreover, wind can lift the solar module known therefrom relatively easily at its lower edge. The expensive solar modules threaten to become detached from the roof and be destroyed. These problems arise also in connection with the solar modules known from printed publication U.S. Pat. No. 7,012,188 B2.

Printed publication DE 29521509 U1 discloses solar modules provided with a flat, insufficiently torsion-resistant frame. At least two spacers are provided underneath the frame which also are incapable of stabilizing the frame sufficiently. A hook which is hooked into a base structure of the roof is attached on the underside of the spacers. The solar modules known therefrom are also insufficiently secured on a roof.

### SUMMARY OF THE INVENTION

It is the object of the invention to provide a device for attaching solar modules that enables an agreeable integration into a roof and is easy to install.

In order to achieve the object, a frame is provided in one embodiment which consists of two lateral frame members, an upper and a lower frame member. Each of the four frame members comprises an area having a rectangular cross section with two long and two narrow sides. The four frame members are interconnected such that the long sides are disposed perpendicular to the main surface of the solar module or the solar cell. It is thereby achieved that the frame is torsion-resistant. Therefore, the solar module can be transported and mounted with comparatively few problems.

Compared with the other frame members, the upper frame member comprises a downwardly projecting portion configured such that it can be attached behind a batten in order thus to retain the solar module on a pitched roof. It is possible in this way to attach the solar module on a batten like a roofing tile.

However, such a solar module may be blown off during a storm just like a roofing tile. However, the damage would be considerably greater as compared with a roofing tile. In order to avoid such damage without much effort, the downwardly projecting portion comprises a bore. Through this bore, the solar module can be attached with at least one bolt to the roofing slab. Thus, the solar module is secured against storm damage in an improved manner, and can still be mounted simply and reliably.

In one embodiment of the invention, the lower frame member comprises a projecting portion, which on the upper side extends parallel to the main surface of the solar module. It is intended to rest this projecting portion on an upper frame member which belongs to an adjacent lower solar module already attached on a roof. It is thus achieved that two such solar modules form a continuous surface which protects the roof from penetration of water. Because the projecting portion of the lower frame member can be very thin, there is an almost invisible step in the transition from a lower solar module to an adjacent upper solar module on a pitched roof. The solar modules can thus be attached to the roof in a correspondingly pleasing fashion.

In order to protect the expensive solar modules from storm damage in a more improved manner, a lower and an upper frame member can for example be provided with groove and tongue or two comparable coupling members. If the tongue is pushed into the groove, a lower frame member is thus also attached. A lower frame member thus cannot be lifted in case of storm. Thus, solar modules are protected against storm damage in a more improved manner.

However, it was found to be particularly advantageous if such additional coupling members are dispensed with and if the solar modules are instead mounted on a roof such that the portions with the rectangular cross section are closely adjacent. If the projecting portions of each of the upper frame members are attached to a batten bolts, then a lower frame member cannot be lifted out because this is prevented by the adjacent upper frame member of a solar module attached below it. A particularly good protection against storm damage is thus also achieved without providing room for additional coupling members. Moreover, no care must be taken during assembly that such additional coupling members are connected with each other.

In one embodiment of the invention, the lateral frame members comprise grooves and tongues, with the groove comprising a gasket, in particular in its interior. A tongue of a lateral frame member is pushed into the groove of an adjacent frame member. A watertight connection between the two solar modules is provided by the gasket. As a result, a surface which protects the roof from the penetration by water is thereby created.

In one embodiment of the invention, the frame is made of metal. In particular of aluminum. However, the use of a fiberglass-reinforced material is particularly preferable. This has the advantage of being light and electrically non-conductive. Moreover, it can have almost the same expansion coefficient as a solar cell, which corresponds or is similar to the expansion coefficient of glass, if the material reinforced with fiberglass has been appropriately and suitably reinforced. At the same time, the fiberglass-reinforced material can be provided with an UV resistant color. This makes it possible to vary the colors and to make the color correspond to the color of the roof in a particularly simple manner.

The frame particularly preferably consists of four individual parts, that is, of two individual lateral frame members as well as one upper and one lower frame member. The four different frame members are positively connected with each other by means of corner joints. In particular by positive fit. This makes a particularly easy connection of a solar cell with the frame possible. A cost-effective production is thus possible.

### BRIEF DESCRIPTION OF THE DRAWINGS

FIG. 1 is a lateral cross-section view of the present invention;

FIG. 2 is an enlarged section of FIG. 1;

FIG. 3 is a cross-section of FIG. 2; and

FIG. 4 is a perspective view of the present invention.

### DETAILED DESCRIPTION OF THE INVENTION

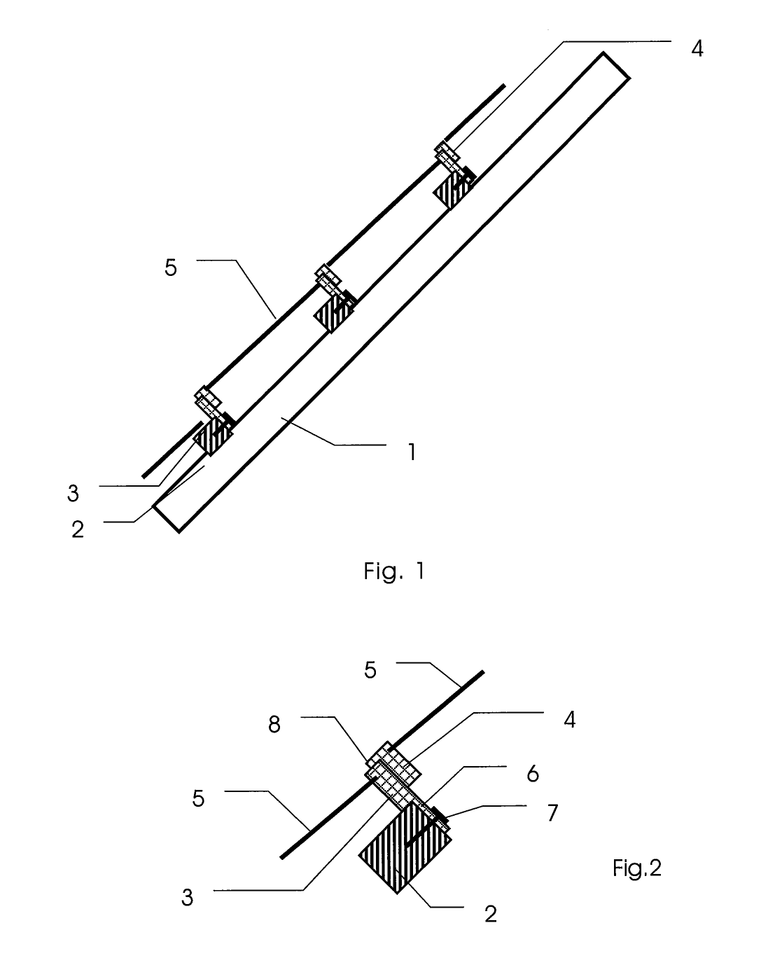

A pitched roof has a plurality of parallel rafters 1 on which horizontally extending battens 2 are attached, as is illustrated in FIG. 1 in a lateral cross-sectional view. FIG. 1 shows upper frame members 3 and lower frame members 3 which respectively frame a solar cell 5.

FIG. 2 shows an enlarged section from FIG. 1.

The upper frame member has a projecting member 6 on one end. This member projects downwardly relative to the other parts of the frame. A solar module is thereby laid on the roof like a tile. The projecting member or the downwardly projecting portion 6 engages behind a batten 2, similar to roofing tiles. Thus, the solar module has been laid on a roof like a roofing tile.

The projecting member 6 has holes in order to bolt the module to the batten by means of bolts 7. The lower frame member 4 of a first solar module shown in FIG. 2 is adjacent to the upper frame member 3 of a second solar module located below it. It has a projecting portion 8 which extends parallel to the main surface of the solar cells 5. In the assembled state, the projecting portion or projecting area 8 rests on the upper frame member of the second lower solar module. The transition is thus sufficiently well protected against the penetration by water. However, it is also possible to provide laminated foils in such a transition area. These laminated foils cause vibration damping so that no rattling noises are generated.

Moreover, grooves with gaskets located therein are provided in the frame members in order to push the edges of the solar cells 5 into these grooves and thus connect them with the frames in a watertight manner.

The lower frame member 4 of the first solar module adjoins the upper frame member of the second solar module so closely that the lower frame member cannot be lifted up anymore. Thus, an attachment is ensured also in this lower area of a solar module.

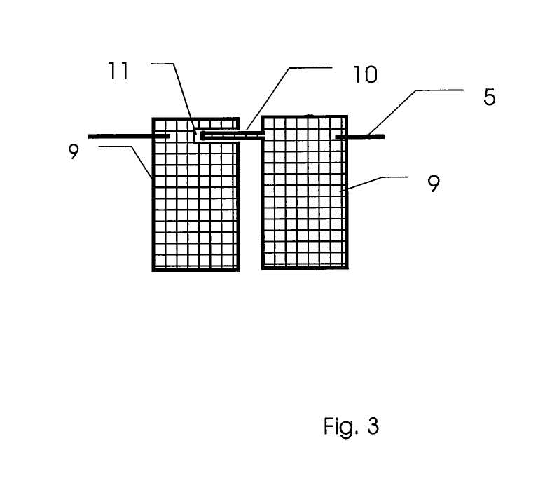

The lateral frame members 9 comprises a tongue-and-groove system 10, 11 as FIG. 3 shows in cross section. The tongue-and-groove system preferably is located at the level of the solar cells. If a solar module is connected with a subsequent one on this side, the groove 10 is pushed into the tongue 11. A gasket, which is not shown, is located in the groove. This gasket particularly preferably consist of a sponge rubber sealing strip.

By means of this groove-rail system, it is achieved that leak-tightness is ensured at these sides as well. Thus, it is not necessary to additionally provide a water seal in this area, for example, by means of a separate covering.

Moreover, the tongue-and-groove system makes it possible that attention need not be paid to a very precise assembly. Particularly preferably, the possible tolerance is at least 3 mm. Such a tolerance is made possible particularly if a sponge rubber sealing strip is used.

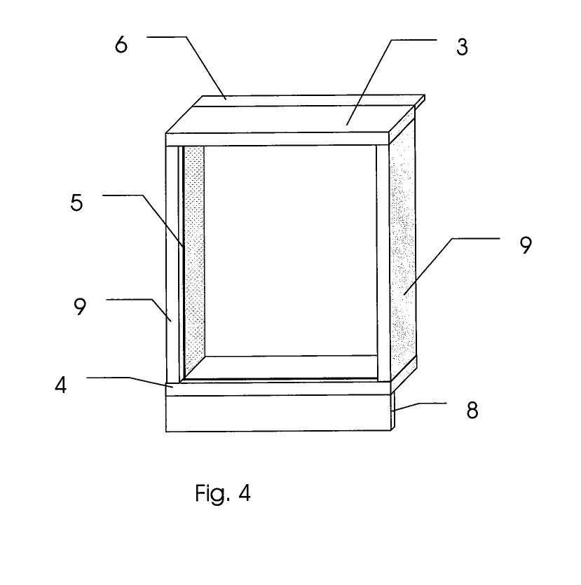

FIG. 4 outlines a three-dimensional representation, but without groove and tongue on the lateral frame member 9 and holes in the projecting portion 6.

The solar modules can be mounted on a roof very easily. A module is lifted over the roof using a crane and a suction cup. It now only has to be lowered and bolted in a suitable manner.

Each frame is designed such that there is a shingle-like overlapping in the edge areas from the top towards the bottom. The system thus fulfils a dual function. On the one hand, the modules are retained such that no additional member is required for sealing. On the other hand, they contribute to the energy supply. Moreover, the frame members protect the modules from damage during packaging, transport and assembly.

The modules may be equipped with photovoltaic elements. They can be equipped with solar collectors for hot water. A combination on a house's roof is readily possible. This applies especially if the same frame system and matching sizes are used.

The connection the hot-water system or to a power system does not have to be modified as compared with conventional solutions.

The frame system is advantageous in that it behaves like a roofing tile. Thus, there is also a back ventilation. In the case of a photovoltaic system, this is advantageous in order not to let it heat up. Efficiency is thus maintained if the photovoltaic system is not heated up too strongly. This especially applies if the frame is relatively wide in accordance with the first claim, so that there is a large volume behind the solar cell. A separate cooling system is not required.

Producing the frame members is possible without any problems. For example, the frame members can also be produced by pultrusion. The transitions must then be beveled. Possibly, depending on the embodiment, some parts must be finished, for example provided with recesses, using a milling cutter. A possibly advantageous recess could also be provided by punching.

1. Solar module for installation in a pitched roof, comprising:
a frame; and a solar cell held by the frame, wherein the frame comprises:
two lateral frame members; and
an upper and a lower frame member which have an area with a rectangular cross section,
wherein the rectangular cross section has two long and two narrow sides, wherein the two lateral, upper and lower frame members are interconnected such that the long sides include a right angle with the solar cell, and
wherein the upper frame member has such a downwardly projecting portion which makes support for the solar module on a batten possible in a pitched roof.

2. Solar module according to claim 1, further comprising a projecting portion of the lower frame member which is disposed parallel to the surface of the solar cell.

3. Solar module according to claim 1, comprising a tongue-and-groove system at the lateral frame members.

4. Solar module according to claim 1, further comprising a gasket which makes a watertight connection of the groove with the tongue possible.

5. Solar module according to claim 1, wherein the frame members consist of fiberglass-reinforced plastics.

6. Solar module according to claim 1, wherein the frame consists of four individual frame members connected by means of corner joints, preferably by positive fit.

7. Pitched roof, according to claim 1, comprising:
a solar module for installation into a pitched roof, comprising:
a frame; and
a solar cell held by the frame, wherein the frame comprises two lateral, an upper and a lower frame members, wherein the upper frame member has a downwardly projecting portion attached with bolts to a batten in a pitched roof.

8. Pitched roof according to claim 7, wherein the lower frame member of a first solar module laterally adjoins an upper frame member of a second solar module so that the lower frame member is thereby held in its position.

9. Pitched roof according to claim 7, further comprising a projecting portion of a lower frame member which rests on an upper frame member such that a protection against the penetration of water is thereby provided between two solar modules.

10. Method for mounting a solar module comprising the step of hooking the solar module of claim 1, with its downwardly projecting portion is hooked into a batten of a pitched roof.
